(19) United States
(12) Patent Application Publication
(10) Pub. No.: US 2025/0309841 A1
(43) Pub. Date: Oct. 2, 2025

(54) PRE-POWER AMPLIFIER CIRCUITRY USING ACTIVE TERMINATION

(71) Applicant: Texas Instruments Incorporated, Dallas, TX (US)

(72) Inventors: Nagarajan Viswanathan, Bangalore (IN); Karthikeyan Gunasekaran, Bangalore (IN); Jagannathan Venkataraman, Bangalore (IN)

(21) Appl. No.: 18/620,551

(22) Filed: Mar. 28, 2024

(51) Int. Cl. H03F 3/24; H03F 1/08; H03M 1/74

(52) U.S. Cl. CPC H03F 3/245; H03F 1/086; H03M 1/742; H03F 2200/451

(57) ABSTRACT

An example apparatus includes: voltage buffer circuitry including: source follower circuitry having a terminal; and a resistor having a first terminal and a second terminal, the first terminal of the resistor coupled to the terminal of the source follower circuitry; and driver circuitry including: a first transistor having a first terminal and a second terminal, the first terminal of the first transistor coupled to the second terminal of the resistor; and a second transistor having a terminal coupled to the second terminal of the first transistor.

### TECHNICAL FIELD

This description relates generally to transmitter circuitry and, more particularly, to pre-power amplifier circuitry using active termination.

### BACKGROUND

As electronics continue to become increasingly complex, circuitry has become capable of operating at high speeds with decreasing package sizes. Transmission speeds of communication systems continue to increase as electronics continue to advance. Thus, transmitter circuitry has to accurately generate transmission signals at high speeds.

### SUMMARY

For methods and apparatus to improve pre-power amplifier circuitry, an example apparatus includes voltage buffer circuitry including: source follower circuitry having a terminal; and a resistor having a first terminal and a second terminal, the first terminal of the resistor coupled to the terminal of the source follower circuitry; and driver circuitry including: a first transistor having a first terminal and a second terminal, the first terminal of the first transistor coupled to the second terminal of the resistor; and a second transistor having a terminal coupled to the second terminal of the first transistor. Other examples are described.

For methods and apparatus to improve pre-power amplifier circuitry, an example apparatus includes a digital-to-analog converter (DAC) having a first terminal and a second terminal; and pre-power amplifier circuitry including: matching circuitry having a terminal; voltage buffer circuitry having a first terminal and a second terminal, the first terminal of the voltage buffer circuitry coupled to the first terminal of the DAC; and driver circuitry having a first terminal and a second terminal, the first terminal of the driver circuitry coupled to the terminal of the DAC, the second terminal of the driver circuitry coupled to the terminal of the matching circuitry and the terminal of the voltage buffer circuitry. Other examples are described.

For methods and apparatus to improve pre-power amplifier circuitry, an example apparatus includes driver circuitry having a first terminal and a second terminal; a resistor having a first terminal and a second terminal, the first terminal of the resistor coupled to the first terminal of the driver circuitry; source follower circuitry having a first terminal, a second terminal, and a third terminal, the first terminal of the source follower circuitry coupled to the second terminal of the resistor; a first supply terminal coupled to the second terminal of the driver circuitry and the second terminal of the source follower circuitry; and a second supply terminal coupled to the third terminal of the source follower circuitry. Other examples are described.

### BRIEF DESCRIPTION OF THE DRAWINGS

FIG. 1 is a block diagram of an example communication system including pre-power amplifier circuitry that uses voltage buffer circuitry to actively terminate signals.

FIG. 2 is a schematic diagram of an example implementation of the pre-power amplifier circuitry of FIG. 1.

FIG. 3 is a schematic diagram of another example implementation of the pre-power amplifier circuitry of FIG. 1 including example gain calibration circuitry.

FIG. 4 is a schematic diagram of yet another example implementation of the pre-power amplifier circuitry of FIG. 1 including example gain calibration circuitry.

FIG. 5 is a flowchart representative of example operations that may be executed, instantiated, and/or performed to implement the pre-power amplifier circuitry of FIGS. 1, 2, 3, and 4.

FIG. 6 is a plot of an example bandwidth of the pre-power amplifier circuitry of FIGS. 1, 2, 3, and 4.

FIG. 7 is a plot of an example noise reflection of the pre-power amplifier circuitry of FIGS. 1, 2, 3, and 4.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

As electronics continue to become increasingly complex, circuitry has become capable of operating at high speeds with decreasing package sizes. Transmission speeds of communication systems continue to increase as electronics continue to advance. Thus, transmitter circuitry has to accurately generate transmission signals at high speeds.

In radio frequency (RF) systems, transmitter circuitry receives a digital signal from signal processing circuitry. The transmitter circuitry includes a digital-to-analog converter (DAC) that converts the digital signal to an analog signal for transmission. The transmitter circuitry further includes pre-power amplifier circuitry that conditions the analog signal for providing to a power amplifier. In order for the transmitter circuitry to accommodate increasing transmission speeds, both the DAC and the pre-power amplifier circuitry have to support the increasing transmission speeds.

In closed-loop designs, the pre-power amplifier circuitry includes one or more closed loop amplifiers to condition the analog signal. Closed-loop pre-power amplifier circuitry increases the signal strength of the analog signal and has relatively low noise reflection (e.g., S22 value) responsive to the one or more closed-loop amplifiers. Advantageously, relatively low noise reflection increases accuracy of the system. However, the complexity, cost, and size of stabilizing the one or more closed-loop amplifiers to meet timing constraints of RF frequencies disincentivizes the use of closed-loop pre-power amplifier circuitry in RF applications.

In open-loop designs, the pre-power amplifier circuitry includes driver circuitry, parasitic matching circuitry, and a termination resistor. The driver circuitry increases the signal strength of the analog signal. The parasitic matching circuitry accounts for parasitics of both the driver circuitry and the electrical connection to the power amplifier. In RF systems, the parasitic matching circuitry accounts for a parasitic of the driver circuitry and a parasitic of a coaxial connector. The termination resistor is coupled between an alternating current (AC) ground and the coaxial connector. The termination resistor is structured to absorb signal incident and reduce reflected signals, which improves the performance of the transmitter circuitry. In some designs, the termination resistor has a resistance equal to the impedance of the transmission line, which absorb signal incident and reduce reflected signals. However, the termination resistor adds an additional current path to the AC ground. The driver circuitry needs to also sink currents from the additional current path to accurately generate a replica of the analog signal for transmission. Sizes of components of the driver circuitry are increased to accommodate the additional current from the termination resistor. Increasing the sizes of the components of the driver circuitry reduces a bandwidth of the driver circuitry. Thus, the additional current from the termination resistor decreases the bandwidth of the open-loop pre-power amplifier circuitry, which conflicts with increasing transmission speeds of RF systems.

Examples described herein include example methods and apparatus to improve pre-power amplifier circuitry using active termination. In some described examples, the pre-power amplifier circuitry is an open-loop design that includes driver circuitry, parasitic matching circuitry, and voltage buffer circuitry. The driver circuitry includes one or more instances of transistor unit circuitry that are coupled in parallel. The one or more instances of the transistor unit circuitry generate an output voltage using transistors that an analog input signal controls, such as the analog signal from a DAC. The parasitic matching circuitry is coupled to the driver circuitry and the voltage buffer circuitry. The parasitic matching circuitry compensates for a parasitic of the driver circuitry and an electrical connection to the power amplifier circuitry, such as a coaxial connector.

The voltage buffer circuitry further includes source follower circuitry and a resistor. In the described examples, the resistor is coupled between the source follower circuitry and driver circuitry, which has a common source. The source follower circuitry generates a buffered signal responsive to an analog input signal, which represents the analog input signal received by the driver circuitry. The source follower circuitry includes components to generate the buffered signal to be approximately, preferably exactly, equal to the output voltage of the driver circuitry. The source follower circuitry sets a first terminal of the resistor equal to the buffered signal. The driver circuitry sets a second terminal of the resistor to the output voltage. Also, the source follower circuitry absorbs currents resulting from reflected signals.

Advantageously, the voltage difference across the resistor is approximately, preferably exactly, equal to zero when no signals are being reflected. Advantageously, the source follower circuitry provides a current path for reflected signals to flow that is not through the driver circuitry. Advantageously, the resistor and the source follower circuitry prevent the driver circuitry from sinking excess currents resulting from reflected signals. Advantageously, the voltage buffer circuitry allows the driver circuitry to include smaller components that can operate, which increases a bandwidth of the system. Advantageously, using the source follower circuitry to generate the buffered signal increases the bandwidth of the pre-power amplifier circuitry.

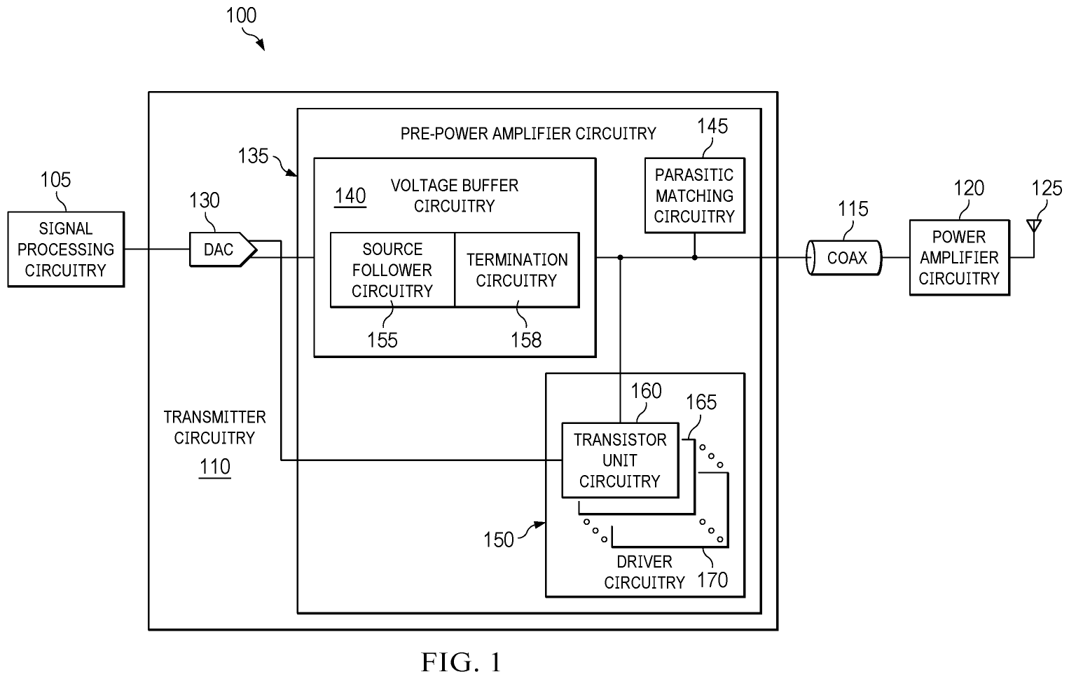

FIG. 1 is a block diagram of an example communication system 100. In the example of FIG. 1, the communication system 100 includes signal processing circuitry 105, transmitter circuitry 110, a coaxial connector 115, power amplifier circuitry 120, and an antenna 125. The example transmitter circuitry 110 of FIG. 1 includes an example digital-to-analog converter (DAC) 130 and example pre-power amplifier (PPA) circuitry 135. The pre-power amplifier circuitry 135 of FIG. 1 includes example voltage buffer circuitry 140, example parasitic matching circuitry 145, and example driver circuitry 150. The example voltage buffer circuitry 140 of FIG. 1 includes example source follower circuitry 155 and example termination circuitry 158. The example driver circuitry 150 of FIG. 1 includes first example transistor unit circuitry 160, second example transistor unit circuitry 165, and third example transistor unit circuitry 170. In some example implementations, the communication system 100 is a part of an RF communication system. In such examples, one or more components of the communication system 100 may be illustrated or described as part of an analog front end (AFE).

In some examples, the communication system 100 is a single integrated circuit (IC) (such as circuitry implemented on a single semiconductor die or on multiple die but within a single IC package). For example, the transmitter circuitry 110 and the power amplifier circuitry 120 may be included on the same semiconductor die. In some examples, communication system 100 may be implemented by two or more ICs in a single IC package to implement a multi-chip module (MCM). In some examples, the communication system 100 may be implemented by two or more ICs (such as two or more IC packages). For example, the transmitter circuitry 110 may be on a first die and the power amplifier circuitry 120 may be on a second die. In some examples, the signal processing circuitry 105 may be on a first die, the transmitter circuitry 110 may be on a second die, and the power amplifier circuitry 120 may be on a third die. Alternatively, one or more hardware circuit components (such as the DAC 130, the pre-power amplifier circuitry 135, etc.) of the transmitter circuitry 110 may be included in the signal processing circuitry 105. Alternatively, one or more hardware circuit components (such as pre-power amplifier circuitry 135, etc.) of the transmitter circuitry 110 may be included in the DAC 130.

The signal processing circuitry 105 has a terminal coupled to the transmitter circuitry 110. The signal processing circuitry 105 is structured as programmable circuitry, which supplies a digital signal. Alternatively, the signal processing circuitry 105 may be replaced with an alternative digital signal source, such as an application specific integrated circuit (ASIC), field programmable gate array (FPGA), etc.

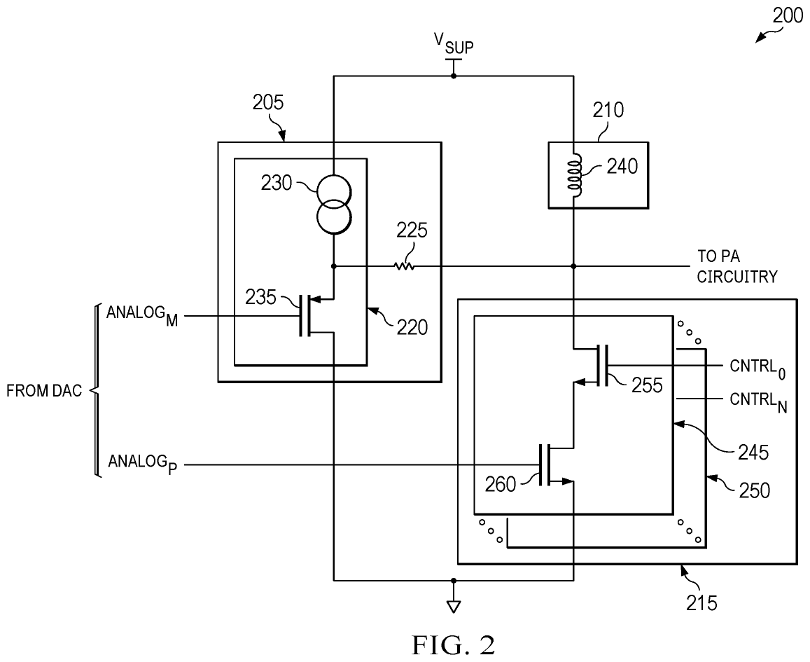

The transmitter circuitry 110 has a first terminal and a second terminal. The first terminal of the transmitter circuitry 110 is coupled to the signal processing circuitry 105. The second terminal of the transmitter circuitry 110 is coupled to the coaxial connector 115. Example implementations of the transmitter circuitry 110 are illustrated and described in connection with FIGS. 2, 3, and 4, below.

The coaxial connector 115 has a first terminal and a second terminal. The first terminal of the coaxial connector 115 is coupled to the transmitter circuitry 110. The second terminal of the coaxial connector 115 is coupled to the power amplifier circuitry 120. In some examples, the communication system 100 may directly couple the transmitter circuitry 110 to the power amplifier circuitry 120. In such examples, the coaxial connector 115 may be replaced or removed. In other examples, the communication system 100 may be modified to replace the coaxial connector 115 with an alternative type of connection.

The power amplifier circuitry 120 has a first terminal and a second terminal. The first terminal of the power amplifier circuitry 120 is coupled to the coaxial connector 115. The second terminal of the power amplifier circuitry 120 is coupled to the antenna 125.

The antenna 125 has a terminal coupled to the power amplifier circuitry 120. The antenna 125 may be communicatively coupled to another communication system, which exchanges electromagnetic signals with the communication system 100 using the antenna 125. Alternatively, the antenna 125 may be replaced with an alternative medium to communicatively couple the power amplifier circuitry 120 to alternative circuitry.

The DAC 130 has a first terminal, a second terminal, and a third terminal. The first terminal of the DAC 130 is coupled to the signal processing circuitry 105. The second and third terminals of the DAC 130 are coupled to the pre-power amplifier circuitry 135. In the example of FIG. 1, the DAC 130 has a differential output. In some examples, the DAC 130 has a single ended output. Also, in the example of FIG. 1, the DAC 130 has a single ended input. In some examples, the DAC 130 has a differential input.

The pre-power amplifier circuitry 135 has a first terminal, a second terminal, and a third terminal. The first and second terminals of the pre-power amplifier circuitry 135 are coupled to the DAC 130. The third terminal of the pre-power amplifier circuitry 135 is coupled to the coaxial connector 115. Example implementations of the pre-power amplifier circuitry 135 are illustrated and described in connection with FIGS. 2, 3, and 4, below.

The voltage buffer circuitry 140 has a first terminal and a second terminal. The first terminal of the voltage buffer circuitry 140 is coupled to the DAC 130. The second terminal of the voltage buffer circuitry 140 is coupled to the coaxial connector 115, the parasitic matching circuitry 145, and the driver circuitry 150. Examples of the voltage buffer circuitry 140 are illustrated and described in connection with FIGS. 2, 3, and 4, below.

The parasitic matching circuitry 145 has a terminal coupled to the coaxial connector 115, the voltage buffer circuitry 140, and the driver circuitry 150. The parasitic matching circuitry 145 may be referred to as matching circuitry. Examples of the parasitic matching circuitry 145 are illustrated and described in connection with FIGS. 2, 3, and 4, below. Alternatively, the parasitic matching circuitry 145 may be illustrated or described external to the pre-power amplifier circuitry 135.

The driver circuitry 150 has a first terminal and a second terminal. The first terminal of the driver circuitry 150 is coupled to the DAC 130. The second terminal of the driver circuitry 150 is coupled to the coaxial connector 115, the voltage buffer circuitry 140, and the parasitic matching circuitry 145. Examples of the driver circuitry 150 are illustrated and described in connection with FIGS. 2, 3, and 4, below.

The source follower circuitry 155 is coupled to the DAC 130 and the termination circuitry 158. Examples of the source follower circuitry 155 are illustrated and described in connection with FIGS. 2, 3, and 4, below. The termination circuitry 158 is coupled to the source follower circuitry 155 at a first terminal, and coupled to the coaxial connector 115, the parasitic matching circuitry 145, and the driver circuitry 150, at a second terminal. Examples of the termination circuitry 158 are illustrated and described in connection with FIGS. 2, 3, and 4, below.

The transistor unit circuitry 160 has a first terminal and a second terminal. The first terminal of the transistor unit circuitry 160 is coupled to the DAC 130 and the transistor unit circuitry 165, 170. The second terminal of the transistor unit circuitry 160 is coupled to the coaxial connector 115, the voltage buffer circuitry 140, the parasitic matching circuitry 145, and the transistor unit circuitry 165, 170.

The transistor unit circuitry 165 has a first terminal and a second terminal. The first terminal of the transistor unit circuitry 165 is coupled to the DAC 130 and the transistor unit circuitry 160, 170. The second terminal of the transistor unit circuitry 165 is coupled to the coaxial connector 115, the voltage buffer circuitry 140, the parasitic matching circuitry 145, and the transistor unit circuitry 160, 170.

The transistor unit circuitry 170 has a first terminal and a second terminal. The first terminal of the transistor unit circuitry 170 is coupled to the DAC 130 and the transistor unit circuitry 160, 165. The second terminal of the transistor unit circuitry 170 is coupled to the coaxial connector 115, the voltage buffer circuitry 140, the parasitic matching circuitry 145, and the transistor unit circuitry 160, 165.

Examples of the transistor unit circuitry 160, 165, 170 are illustrated and described in connection with FIGS. 2, 3, and 4, below. In the example of FIG. 1, each of the transistor unit circuitry 160, 165, 170 are instances of transistor unit circuitry coupled in parallel. Alternatively, the driver circuitry 150 may be modified to include any number of instances of one or more of the transistor unit circuitry 160, 165, 170. Also, each instance of the transistor unit circuitry 160, 165, 170 may have a control terminal that is structured to receive a control signal to enable (e.g., make conducting) or disable (e.g., make non-conducting) one or more instances of the transistor unit circuitry 160, 165, 170. Such control terminals are illustrated and described in connection with FIGS. 2, 3, and 4, below.

In example operation, the signal processing circuitry 105 generates a digital signal representing data to be transmitted using the antenna 125. The transmitter circuitry 110 generates an analog output signal responsive to receiving the digital signal from the signal processing circuitry 105. In such example operations, the DAC 130 converts the digital signal to an analog signal. The pre-power amplifier circuitry 135 conditions the analog signal for transmission through the coaxial connector 115 to the power amplifier 120. The power amplifier 120 amplifies the analog signal from the pre-power amplifier circuitry 135. The antenna 125 transmits the amplified signal from the power amplifier 120 by causing electromagnetic waves of the amplified signal to propagate over the air.

In example operations of the pre-power amplifier circuitry 135, the driver circuitry 150 generates an output voltage responsive to an analog signal from the DAC 130 controlling one or more of the transistor unit circuitry 160, 165, 170. The voltage buffer circuitry 140 actively terminates reflected signals from the coaxial connector 115 by buffering an input signal. In such example operations, the source follower circuitry 155 generates a buffered signal to be proportional to the output voltage of the driver circuitry 150 responsive to receiving an analog signal from the DAC 130. In some examples, the source follower circuitry 155 is structured as inverter circuitry, which receives an inverted version of the analog signal that is supplied to the driver circuitry 150. The voltage buffer circuitry 140 uses currents from the source follower circuitry 155 to compensate the buffered signal for currents of reflected signals.

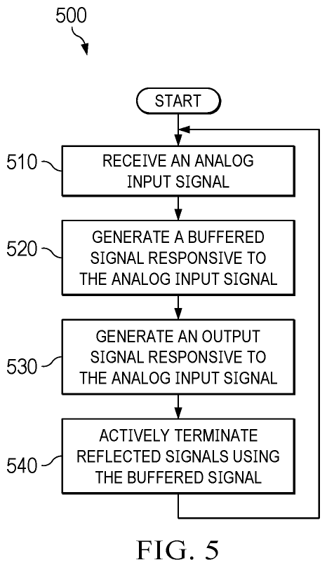

Advantageously, the voltage buffer circuitry 140 terminates reflected signals without supplying excess currents to the driver circuitry 150. Advantageously, decreasing the current to be sunk by the driver circuitry 150 allows the size of components of the transistor unit circuitry 160, 165, 170 to be decreased. Advantageously, decreasing the size of components of the transistor unit circuitry 160, 165, 170 increases the speed at which the driver circuitry 150 may set the output voltage and increases the bandwidth of the pre-power amplifier circuitry 135. Example operations of the pre-power amplifier circuitry 135 are further described in connection with FIG. 5, below.

FIG. 2 is a schematic diagram of example pre-power amplifier circuitry 200, which is an example of the pre-power amplifier circuitry 135 of FIG. 1. In the example of FIG. 2, the pre-power amplifier circuitry 200 includes voltage buffer circuitry 205, parasitic matching circuitry 210, and driver circuitry 215. The example voltage buffer circuitry 205 includes example source follower circuitry 220 and an example resistor 225. The example source follower circuitry 220 includes example current source circuitry 230 and a first example transistor 235. The parasitic matching circuitry 210 of FIG. 2 includes an example inductor 240. The example driver circuitry 215 includes first example transistor unit circuitry 245 and second example transistor unit circuitry 250. The transistor unit circuitry 245 of FIG. 2 includes a second example transistor 255 and a third example transistor 260.

The voltage buffer circuitry 205 has a first terminal, a second terminal, a third terminal, and a fourth terminal. The first terminal of the voltage buffer circuitry 205 is coupled to a supply terminal, which supplies a supply voltage (V_{SUP}). The second terminal of the voltage buffer circuitry 205 is coupled to a common terminal, which supplies a common potential (e.g., ground). In some examples, the common terminal is referred to as a supply terminal. In such examples, the common terminal may receive a second supply voltage, such as AVSS. The third terminal of the voltage buffer circuitry 205 is coupled to a first analog input terminal, which supplies a minus side analog input signal (ANALOG_{M}). In some examples, the third terminal of the voltage buffer circuitry 205 is coupled to the DAC 130. The fourth terminal of the voltage buffer circuitry 205 is coupled to the parasitic matching circuitry 210, the driver circuitry 215 and may be coupled to the coaxial connector 115 of FIG. 1. The voltage buffer circuitry 205 is an example of the voltage buffer circuitry 140 of FIG. 1.

The parasitic matching circuitry 210 has a first terminal and a second terminal. The first terminal of the parasitic matching circuitry 210 is coupled to the supply terminal, which supplies the supply voltage. The second terminal of the parasitic matching circuitry 210 is coupled to the voltage buffer circuitry 205, the driver circuitry 215, and may be coupled to the coaxial connector 115. The parasitic matching circuitry 210 is an example of the parasitic matching circuitry 145 of FIG. 1.

The driver circuitry 215 has a first terminal, a second terminal, and a third terminal. The first terminal of the driver circuitry 215 is coupled to the common terminal, which supplies the common potential. The second terminal of the driver circuitry 215 is coupled to a second analog input terminal, which supplies a plus side analog input signal (ANALOG_{P}). In the example of FIG. 2, the plus and minus side analog input signals are structured as a differential pair of signals. The third terminal of the driver circuitry 215 is coupled to the voltage buffer circuitry 205, the parasitic matching circuitry 210, and may be coupled to the coaxial connector 115. The driver circuitry 215 is an example of the driver circuitry 150 of FIG. 1. In the example of FIG. 2, the driver circuitry 215 is structured as a transconductance amplifier, which uses a configurable transconductance to generate a specific voltage. In some examples, the driver circuitry 215 may be referred to as a transconductance amplifier.

The source follower circuitry 220 has a first terminal, a second terminal, a third terminal, and a fourth terminal. The first terminal of the source follower circuitry 220 is coupled to the supply terminal, which supplies the supply voltage. The second terminal of the source follower circuitry 220 is coupled to the common terminal, which supplies the common potential. The third terminal of the source follower circuitry 220 is coupled to the first analog input terminal, which supplies the minus side analog input signal. The fourth terminal of the source follower circuitry 220 is coupled to the resistor 225. The source follower circuitry 220 is an example of the source follower circuitry 155 of FIG. 1. In the example of FIG. 2, the source follow circuitry 220 is structured to use a supply of current to drive a transistor.

The resistor 225 has a first terminal and a second terminal. The first terminal of the resistor 225 is coupled to the source follower circuitry 220. The second terminal of the resistor 225 is coupled to the parasitic matching circuitry 210, the driver circuitry 215, and may be coupled to the coaxial connector 115. In some examples, the resistor 225 is referred to as a termination resistor. The resistor 225 is an example implementation of the termination circuitry 158 of FIG. 1. Alternatively, the resistor 225 may be illustrated or described external to the voltage buffer circuitry 205. Also, the voltage buffer circuitry 205 may be modified to replace the resistor 225 with alternative circuitry that provides a current path from the driver circuitry 215 to the source follower circuitry 220.

The current source circuitry 230 has a first terminal and a second terminal. The first terminal of the current source circuitry 230 is coupled to the supply terminal, which supplies the supply voltage. The second terminal of the current source circuitry 230 is coupled to the resistor 225 and the transistor 235. In the example of FIG. 2, the current source circuitry 230 is structured as a variable current source. Alternatively, the current source circuitry 230 may be illustrated as fixed current source circuitry or replaced with alternative type of circuitry, such as a charge pump.

The transistor 235 has a first terminal, a second terminal, and a control terminal. The first terminal of the transistor 235 is coupled to the resistor 225 and the current source circuitry 230. The second terminal of the transistor 235 is coupled to the common terminal, which supplies the common potential. The control terminal of the transistor 235 is coupled to the first analog input terminal, which supplies the minus side analog input signal. In the example of FIG. 2, the transistor 235 is structured to have a configurable transconductance, which may be adjusted to generate a reference voltage. In some examples, the transistor 235 may be referred to as a transconductance amplifier.

In the example of FIG. 2, the transistor 235 is a p-channel metal-oxide semiconductor field-effect transistor (MOSFET). Alternatively, with slight modifications the transistor 235 may be a p-channel junction field effect transistor (JFET), a p-channel field-effect transistor (FET), a p-channel insulated-gate bipolar transistor (IGBT), an PNP bipolar junction transistor (BJT) or, with slight modifications, an n-type equivalent device.

The inductor 240 has a first terminal and a second terminal. The first terminal of the inductor 240 is coupled to the supply terminal, which supplies the supply voltage. The second terminal of the inductor 240 is coupled to the voltage buffer circuitry 205, the driver circuitry 215, and may be coupled to the coaxial connector 115. Alternatively, the inductor 240 may be replaced impedance circuitry that compensates for the parasitic of the coaxial connector 115 and the parasitic of the driver circuitry 215.

The transistor unit circuitry 245 has a first terminal, a second terminal, a third terminal, and a control terminal. The first terminal of the transistor unit circuitry 245 is coupled to the common terminal, which supplies the common potential. The second terminal of the transistor unit circuitry 245 is coupled to the second analog input terminal, which supplies the plus side analog input signal. The third terminal of the transistor unit circuitry 245 is coupled to the voltage buffer circuitry 205, the parasitic matching circuitry 210, and the transistor unit circuitry 250. The control terminal of the transistor unit circuitry 245 is coupled to a first driver control terminal, which supplies a first driver control input (CNTRL₀).

The transistor unit circuitry 250 has a first terminal, a second terminal, a third terminal, and a control terminal. The first terminal of the transistor unit circuitry 250 is coupled to the common terminal, which supplies the common potential. The second terminal of the transistor unit circuitry 250 is coupled to the second analog input terminal, which supplies the plus side analog input signal. The third terminal of the transistor unit circuitry 250 is coupled to the voltage buffer circuitry 205, the parasitic matching circuitry 210, and the transistor unit circuitry 245. The control terminal of the transistor unit circuitry 250 is coupled to a second driver control terminal, which supplies a second driver control input (CNTRL_{N}).

The transistor unit circuitry 245, 250 are examples of the transistor unit circuitry 160, 165, 170 of FIG. 1. In the example of FIG. 2, the transistor unit circuitry 250 is another instance of transistor unit circuitry 245, which is coupled in parallel. Alternatively, the driver circuitry 215 may be modified to include any number of instances of one or more instances of the transistor unit circuitry 245.

The transistor 255 has a first terminal, a second terminal, and a control terminal. The first terminal of the transistor 255 is coupled to the voltage buffer circuitry 205, the parasitic matching circuitry 210, the transistor unit circuitry 250, and may be coupled to the coaxial connector 115. The second terminal of the transistor 255 is coupled to the transistor 260. The control terminal of the transistor 255 is coupled to the first driver control terminal, which supplies the first driver control input. In the example of FIG. 2, the transistor 255 is an n-channel MOSFET. Alternatively, with slight modifications the transistor 255 may be an n-channel JFET, an n-channel FET, an n-channel IGBT, an NPN BJT or, with slight modifications, a p-type equivalent device.

The transistor 260 has a first terminal, a second terminal, and a control terminal. The first terminal of the transistor 260 is coupled to the transistor 255. The second terminal of the transistor 260 is coupled to the common terminal, which supplies the common terminal. The control terminal of the transistor 260 is coupled to the second analog input terminal, which supplies the plus side analog input signal. In the example of FIG. 2, the transistor 260 is an n-channel MOSFET. Alternatively, with slight modifications the transistor 260 may be an n-channel JFET, an n-channel FET, an n-channel IGBT, an NPN BJT or, with slight modifications, a p-type equivalent device.

In example operations, the driver circuitry 215 generates an output voltage responsive to the plus side analog input signal from the DAC 130 controlling the transistor 260 of the transistor unit circuitry 245. In some examples, the plus side analog input signal controls transistors of the transistor unit circuitry 245, 250. In such examples, the driver control input signals of the transistor unit circuitry 245, 250 turn on the transistor 255.

In such example operations, the voltage buffer circuitry 205 actively terminates reflected signals from the coaxial connector 115 by buffering an input signal. The source follower circuitry 220 generates a buffered signal responsive to the minus side analog input signal controlling the transistor 235. The transistor 235 sources current from the current source circuitry 230 and currents of reflected signals. The transistor 235 sets the buffered signal to be proportional to the output voltage of the driver circuitry 215. In the example of FIG. 2, the source follower circuitry 220 is structured as inverter circuitry responsive to the transistor 235 being a p-channel transistor. The voltage buffer circuitry 205 sets the second terminal of the resistor 225 equal to the buffered signal and the driver circuitry 215 sets the first terminal of the resistor 225 equal to the output voltage. Advantageously, when there are no reflected signals, the resistor does not supply any current. Advantageously, when there are reflected signals, the source follower circuitry 220 uses excess currents from the reflected signal to generate the buffered signal or supplies current to the driver circuitry 215 to prevent reflected signals from adjusting the output voltage. Example operations of the pre-power amplifier circuitry 200 are further described in connection with FIG. 5, below.

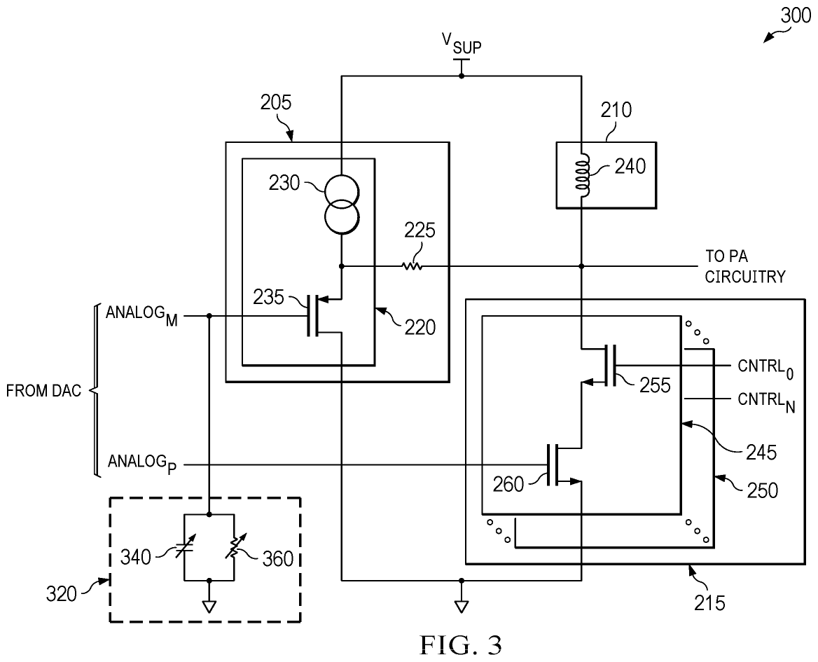

FIG. 3 is a schematic diagram of example pre-power amplifier circuitry 300, which is an example of the pre-power amplifier circuitry 135, 200 of FIGS. 1 and 2. In the example of FIG. 3, the pre-power amplifier circuitry 300 includes the voltage buffer circuitry 205 of FIG. 2, the parasitic matching circuitry 210 of FIG. 2, the driver circuitry 215 of FIG. 2, and gain calibration circuitry 320. The voltage buffer circuitry 205 includes the source follower circuitry 220 of FIG. 2 and the resistor 225 of FIG. 2. The source follower circuitry 220 includes the current source circuitry 230 of FIG. 2 and the transistor 235 of FIG. 2. The parasitic matching circuitry 210 includes the inductor 240 of FIG. 2. The driver circuitry 215 includes the transistor unit circuitry 245, 250 of FIG. 2. The transistor unit circuitry 245 includes the transistors 255, 260 of FIG. 2. The gain calibration circuitry 320 includes an example capacitor 340 and an example resistor 360. The gain calibration circuitry 320 has a terminal coupled to the first analog input terminal, which supplies the minus side analog input signal (ANALOG_{M}), and the voltage buffer circuitry 205.

The capacitor 340 has a first terminal and a second terminal. The first terminal of the capacitor 340 is coupled to the first analog input terminal, which supplies the minus side analog input signal (ANALOG_{M}), the voltage buffer circuitry 205, and the resistor 360. The second terminal of the capacitor 340 is coupled to the common terminal, which supplies the common potential. In some examples, the capacitor 340 has a capacitance that is set responsive to a trim code. In such examples, the capacitance of the capacitor 340 is set during manufacturing or responsive to a calibration process. Alternatively, the capacitance of the capacitor 340 may be fixed.

The resistor 360 has a first terminal and a second terminal. The first terminal of the resistor 360 is coupled to the first analog input terminal, which supplies the minus side analog input signal (ANALOG_{M}), the voltage buffer circuitry 205, and the capacitor 340. The second terminal of the resistor 360 is coupled to the common terminal, which supplies the common potential. In some examples, the resistor 360 has a resistance that is set responsive to a trim code. In such examples, the resistance of the resistor 360 is set during manufacturing or responsive to a calibration process. Alternatively, the resistance of the resistor 360 may be fixed.

In example operation, the gain calibration circuitry 320 adjusts an impedance at the control terminal of the transistor 235. In such example operations, the gain calibration circuitry 320 adjusts a gain of the buffered signal in relation to the output voltage responsive to adjusting the impedance at the control terminal of transistor 235. Ideally, the buffered signal is equal to the output signal. However, non-ideal characteristics of components create differences between the buffered signal and the output signal. The gain correction circuitry 320 corrects for these non-ideal characteristics responsive to setting the capacitance of the capacitor 340 and the resistance of the resistor 360 to set the gain of the buffered signal in comparison to the output signal. In some examples, during a calibration process, manufacturers adjust the capacitance of the capacitor 340 and the resistance of the resistor 360 to set the gain of the buffered signal and output signal to be approximately, preferably exactly, equal to one. Advantageously, the gain calibration circuitry 320 corrects non-ideal gain characteristics between the driver circuitry 215 and the source follower circuitry 220.

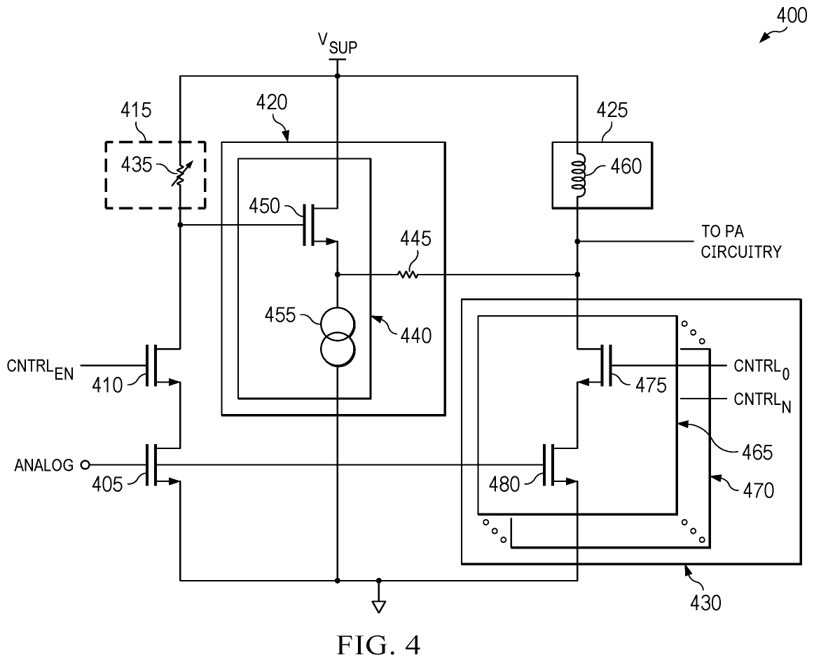

FIG. 4 is a schematic diagram of example pre-power amplifier circuitry 400, which is another example of the pre-power amplifier circuitry 135, 200, 300 of FIGS. 1, 2, and 3. In the example of FIG. 4, the pre-power amplifier circuitry 400 includes a first transistor 405, a second transistor 410, gain calibration circuitry 415, voltage buffer circuitry 420, parasitic matching circuitry 425, and driver circuitry 430. The gain calibration circuitry 415 of FIG. 4 includes an example resistor 435. The voltage buffer circuitry 420 of FIG. 4 includes example source follower circuitry 440 and an example resistor 445. The source follower circuitry 440 of FIG. 4 includes a third example transistor 450 and example current source circuitry 455. The parasitic matching circuitry 425 of FIG. 4 includes an example inductor 460. The driver circuitry 430 of FIG. 4 includes first example transistor unit circuitry 465 and the second example transistor unit circuitry 470. The transistor unit circuitry 465 of FIG. 4 includes a fourth example transistor 475 and a fifth example transistor 480.

The transistor 405 has a first terminal, a second terminal, and a control terminal. The first terminal of the transistor 405 is coupled to the transistor 410. The second terminal of the transistor 405 is coupled to the common terminal, which supplies the common potential. The control terminal of the transistor 405 is coupled to an analog input terminal, which supplies an analog input signal (ANALOG). In the example of FIG. 4, the transistor 405 is an n-channel MOSFET. Alternatively, with slight modifications the transistor 405 may be an n-channel JFET, an n-channel FET, an n-channel IGBT, an NPN BJT or, with slight modifications, a p-type equivalent device.

The transistor 410 has a first terminal, a second terminal, and a control terminal. The first terminal of the transistor 410 is coupled to the gain calibration circuitry 415 and the voltage buffer circuitry 420. The second terminal of the transistor 410 is coupled to the transistor 405. The control terminal of the transistor 410 is coupled to an active termination control terminal, which supplies an active termination control signal (CNTRL_{EN}). In the example of FIG. 4, the transistor 410 is an n-channel MOSFET. Alternatively, with slight modifications the transistor 410 may be an n-channel JFET, an n-channel FET, an n-channel IGBT, an NPN BJT or, with slight modifications, a p-type equivalent device.

The gain calibration circuitry 415 has a first terminal and a second terminal. The first terminal of the gain calibration circuitry 415 is coupled to the supply terminal, which supplies the supply voltage. The second terminal of the gain calibration circuitry 415 is coupled to the transistor 410 and the voltage buffer circuitry 420. The gain calibration circuitry 415 of FIG. 4 is another example of the gain calibration circuitry 320 of FIG. 3.

The voltage buffer circuitry 420 has a first terminal, a second terminal, a third terminal, and a fourth terminal. The first terminal of the voltage buffer circuitry 420 is coupled to the supply terminal, which supplies the supply voltage. The second terminal of the voltage buffer circuitry 420 is coupled to the common terminal, which supplies the common potential. The third terminal of the voltage buffer circuitry 420 is coupled to the transistor 410 and the gain calibration circuitry 415. The fourth terminal of the voltage buffer circuitry 420 is coupled to the parasitic matching circuitry 425, the driver circuitry 430, and may be coupled to the coaxial connector 115 of FIG. 1. The voltage buffer circuitry 420 is another example of the voltage buffer circuitry 140, 205 of FIGS. 1, 2, and 3.

The parasitic matching circuitry 425 has a first terminal and a second terminal. The first terminal of the parasitic matching circuitry 425 is coupled to the supply terminal, which supplies the supply voltage. The second terminal of the parasitic matching circuitry 425 is coupled to the voltage buffer circuitry 420, the driver circuitry 430, and may be coupled to the coaxial connector 115. The parasitic matching circuitry 425 is another example of the parasitic matching circuitry 145, 210 of FIGS. 1, 2, and 3. As described herein, the parasitic matching circuitry 145, 200, 425 are structured to compensate for non-ideal characteristics, such as impedances of the coaxial connector 115 of FIG. 1, the transistor unit circuitry 160, 165, 170, etc.

The driver circuitry 430 has a first terminal, a second terminal, and a third terminal. The first terminal of the driver circuitry 430 is coupled to the common terminal, which supplies the common potential. The second terminal of the driver circuitry 430 is coupled to the analog input terminal, which supplies the analog input signal. The third terminal of the driver circuitry 430 is coupled to the voltage buffer circuitry 420, the parasitic matching circuitry 425, and may be coupled to the coaxial connector 115. The driver circuitry 430 is another example of the driver circuitry 150, 215 of FIGS. 1, 2, and 3. In the example of FIG. 4, the driver circuitry 430 is structured as a transconductance amplifier, which uses a configurable transconductance to generate a specific voltage. In some examples, the driver circuitry 430 may be referred to as a transconductance amplifier.

The resistor 435 has a first terminal and a second terminal. The first terminal of the resistor 435 is coupled to the supply terminal, which supplies the supply voltage. The second terminal of the resistor 435 is coupled to the transistor 410 and the voltage buffer circuitry 420. In the example of FIG. 4, the resistor 435 is structured as a variable resistor, which has a controllable resistance. In such examples, the resistor 435 has a control terminal coupled to a trim input, which sets the resistance of the resistor 435. Alternatively, the resistor 435 may be illustrated and described as a resistor having a fixed resistance.

The source follower circuitry 440 has a first terminal, a second terminal, a third terminal, and a fourth terminal. The first terminal of the source follower circuitry 440 is coupled to the supply terminal, which supplies the supply voltage. The second terminal of the source follower circuitry 440 is coupled to the common terminal, which supplies the common potential. The third terminal of the source follower circuitry 440 is coupled to the transistor 410 and the gain calibration circuitry 415. The fourth terminal of the source follower circuitry 440 is coupled to the resistor 445. The source follower circuitry 440 is another example of the source follower circuitry 155, 220 of FIGS. 1, 2, and 3.

The resistor 445 has a first terminal and a second terminal. The first terminal of the resistor 445 is coupled to the source follower circuitry 440. The second terminal of the resistor 445 is coupled to the parasitic matching circuitry 425, the driver circuitry 430, and may be coupled to the coaxial connector 115. The resistor 445 is another example of the resistor 225 of FIGS. 2 and 3. In some examples, the resistor 445 is referred to as a termination resistor.

The transistor 450 has a first terminal, a second terminal, and a control terminal. The first terminal of the transistor 450 is coupled to the supply terminal, which supplies the supply voltage. The second terminal of the transistor 450 is coupled to the resistor 445 and the current source circuitry 455. The control terminal of the transistor 450 is coupled to the transistor 410 and the gain calibration circuitry 415. In the example of FIG. 4, the transistor 450 is structured to have a configurable transconductance, which may be adjusted to generate a reference voltage. In some examples, the transistor 450 may be referred to as a transconductance amplifier. In the example of FIG. 4, the transistor 450 is an n-channel MOSFET. Alternatively, with slight modifications the transistor 450 may be an n-channel JFET, an n-channel FET, an n-channel IGBT, an NPN BJT or, with slight modifications, a p-type equivalent device.

The current source circuitry 455 has a first terminal and a second terminal. The first terminal of the current source circuitry 455 is coupled to the resistor 445 and the transistor 450. The second terminal of the current source circuitry 455 is coupled to the common terminal, which supplies the common potential. In the example of FIG. 4, the current source circuitry 455 is structured as a variable current source. Alternatively, the current source circuitry 455 may be illustrated as fixed current source circuitry or replaced with alternative type of circuitry, such as a charge pump.

The inductor 460 has a first terminal and a second terminal. The first terminal of the inductor 460 is coupled to the supply terminal, which supplies the supply voltage. The second terminal of the inductor 460 is coupled to the voltage buffer circuitry 420, the driver circuitry 430, and may be coupled to the coaxial connector 115. The inductor 460 is another example of the inductor 240 of FIGS. 2 and 3. Alternatively, the inductor 460 may be replaced impedance circuitry that compensates for the parasitic of the coaxial connector 115 and the parasitic of the driver circuitry 430.

The transistor unit circuitry 465 has a first terminal, a second terminal, a third terminal, and a control terminal. The first terminal of the transistor unit circuitry 465 is coupled to the common terminal, which supplies the common potential. The second terminal of the transistor unit circuitry 465 is coupled to the analog input terminal, which supplies the analog input signal. The third terminal of the transistor unit circuitry 465 is coupled to the voltage buffer circuitry 420, the parasitic matching circuitry 425, and the transistor unit circuitry 470. The control terminal of the transistor unit circuitry 465 is coupled to a first driver control terminal, which supplies a first driver control input (CNTRL₀).

The transistor unit circuitry 470 has a first terminal, a second terminal, a third terminal, and a control terminal. The first terminal of the transistor unit circuitry 470 is coupled to the common terminal, which supplies the common potential. The second terminal of the transistor unit circuitry 470 is coupled to the analog input terminal, which supplies the analog input signal. The third terminal of the transistor unit circuitry 470 is coupled to the voltage buffer circuitry 420, the parasitic matching circuitry 425, and the transistor unit circuitry 465. The control terminal of the transistor unit circuitry 470 is coupled to a second driver control terminal, which supplies a second driver control input (CNTRL_{N}).

The transistor unit circuitry 465, 470 are other examples of the transistor unit circuitry 160, 165, 170, 245, 250 of FIGS. 1 and 2. In the example of FIG. 4, the transistor unit circuitry 470 is another instance of transistor unit circuitry 465, which is coupled in parallel. Alternatively, the driver circuitry 430 may be modified to include any number of instances of one or more instances of the transistor unit circuitry 465.

The transistor 475 has a first terminal, a second terminal, and a control terminal. The first terminal of the transistor 475 is coupled to the voltage buffer circuitry 420, the parasitic matching circuitry 425, the transistor unit circuitry 470, and may be coupled to the coaxial connector 115. The second terminal of the transistor 475 is coupled to the transistor 480. The control terminal of the transistor 475 is coupled to the first driver control terminal, which supplies the first driver control input. In the example of FIG. 4, the transistor 475 is an n-channel MOSFET. Alternatively, with slight modifications the transistor 475 may be an n-channel JFET, an n-channel FET, an n-channel IGBT, an NPN BJT or, with slight modifications, a p-type equivalent device.

The transistor 480 has a first terminal, a second terminal, and a control terminal. The first terminal of the transistor 480 is coupled to the transistor 475. The second terminal of the transistor 480 is coupled to the common terminal, which supplies the common terminal. The control terminal of the transistor 480 is coupled to the second analog input terminal, which supplies the plus side analog input signal. In the example of FIG. 2, the transistor 480 is an n-channel MOSFET. Alternatively, with slight modifications the transistor 480 may be an n-channel JFET, an n-channel FET, an n-channel IGBT, an NPN BJT or, with slight modifications, a p-type equivalent device.

In example operation, similar to the gain calibration circuitry 320 of FIG. 3, the gain calibration circuitry 415 adjusts an impedance at the control terminal of the transistor 450 set the gain of the buffered signal in comparison to the output signal. In some examples, during a calibration process, manufacturers adjust the resistance of the resistor 435 to set the gain of the buffered signal and output signal to be approximately, preferably exactly, equal to one. Advantageously, the gain calibration circuitry 415 corrects non-ideal gain characteristics between the driver circuitry 430 and the source follower circuitry 440. Example operations of the pre-power amplifier circuitry 400 are further described in connection with FIG. 5, below.

FIG. 5 is a flowchart representative of example operations 500 that may be executed, instantiated, and/or performed to implement the pre-power amplifier circuitry 135, 200, 300, 400 of FIGS. 1, 2, 3, and 4. The example operations 500 of FIG. 5 begin at Block 510, at which the voltage buffer circuitry 140, 205, 420 of FIGS. 1, 2, 3, and 4 and the driver circuitry 150, 215, 430 of FIGS. 1, 2, 3, and 4 receive an analog input signal. (Block 510). In some examples, the voltage buffer circuitry 140, 205 receive a minus side analog input signal and the driver circuitry 150, 215 receive a plus side analog input signal. In such examples, the plus side and minus side analog input signals are a differential pair of input signals that represent the analog input signal. In other examples, the voltage buffer circuitry 420 and the driver circuitry 430 receive a single-ended analog input signal.

The voltage buffer circuitry 140, 205, 420 generates a buffered signal responsive to the analog input signal. (Block 520). In some examples, the source follower circuitry 155, 220, 440 of FIGS. 1, 2, 3, and 4 generates the buffered signal by following the voltage of the analog input signal. In such examples, the analog input signal controls the transistors 235, 450 of FIGS. 2, 3, and 4, which sets a transconductance of the transistors 235, 450 proportional to the analog input signal. In example operation, the buffered signal is equal to a multiplication of one over the transconductance of the transistors 235, 450 times the current the current source circuitry 230, 455 of FIGS. 2 and 4 supplies to or sinks current from the transistors 235, 450. In some examples, such as in FIGS. 2 and 3, the source following circuitry 220 inverts the minus side analog signal responsive to the transistor 235 being a p-channel MOSFET. Advantageously, the buffered signal of the source follower circuitry 155, 220, 440 is proportional to the analog input signal.

The driver circuitry 150, 215, 430 generates an output signal responsive to the analog input signal. (Block 530). In some examples, the analog input signal controls the transistors 260, 480 of FIGS. 2, 3, and 4, which sets the transconductance of the transistors 260, 480 proportional to the analog input signal. In example operations, the output voltage is equal to a multiplication of one over the transconductance of the transistors 260, 480 times the current from the parasitic matching circuitry 145, 210, 425 of FIGS. 1, 2, 3, and 4. Thus, the output voltage of the pre-power amplifier circuitry 135, 200, 300, 400 is proportional to the analog input signal that controls the transistors 260, 480.

The voltage buffer circuitry 140, 205, 420 actively terminates reflected signals using the buffered signal. (Block 540). In some examples, the source follower circuitry 220, 440 supplies the buffered signal to a first side of the resistors 225, 445 of FIGS. 2, 3, and 4 and the driver circuitries 150, 215, 430 supplies the output voltage to a second side of the resistors 225, 445. In such examples, both the buffered signal and the output signal are proportional to the analog input signal and approximately equal to each one another. In some examples, both the buffered signal and the output signal are proportional to the analog input signal and equal to each one another. In example operations, when the buffered signal and the output signal are equal to each other, no current flows through the resistors 225, 445. In such example operations, the current through the transistor unit circuitry 160, 165, 170, 245, 250, 465, 470 of FIGS. 1, 2, 3, and 4 is limited to the current from the parasitic matching circuitry 145, 210 425. Advantageously, the transistor unit circuitry 160, 165, 170, 245, 250, 465, 470 may include transistors that support smaller current and switch at faster speeds, responsive to decreasing the amount of current flowing through the transistor unit circuitry 160, 165, 170, 245, 250, 465, 470. Advantageously, using such transistors for the transistor unit circuitry 160, 165, 170, 245, 250, 465, 470 increases the bandwidth of the pre-power amplifier circuitry 135, 200, 300, 400.

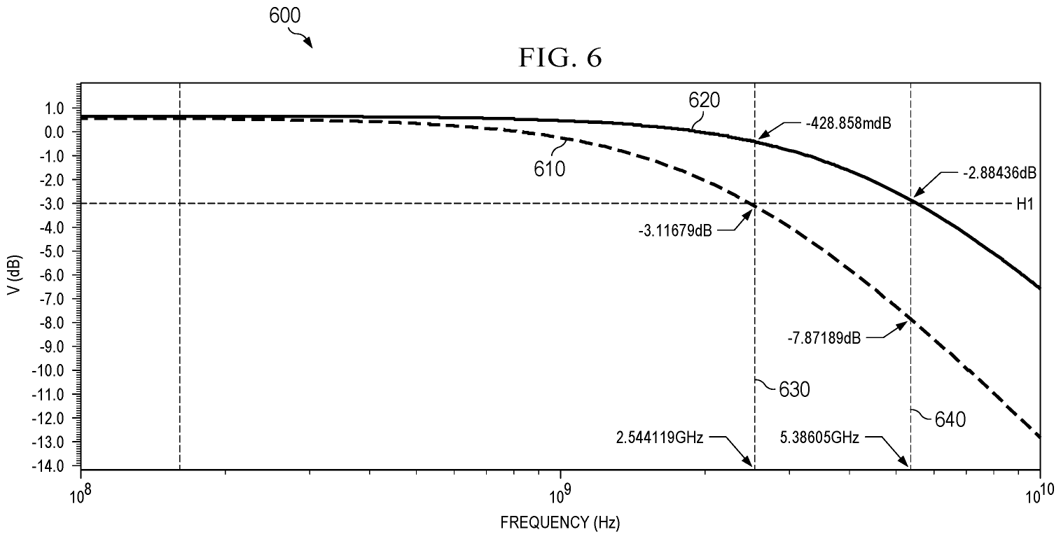

FIG. 6 is a plot 600 of an example bandwidth of the pre-power amplifier circuitry 135, 200, 300, 400 of FIGS. 1, 2, 3, and 4. In the example of FIG. 6, the plot 600 illustrates a reference pre-power amplifier bandwidth 610 and an active termination pre-power amplifier bandwidth 620. The reference pre-power amplifier bandwidth 610 represents the bandwidth of pre-power amplifier circuitry without the source follower circuitry 155, 220, 440 of FIGS. 1, 2, 3, and 4 and the resistors 225, 445 of FIGS. 2, 3, and 4 or, more generally, the voltage buffer circuitry 140, 205, 420 of FIGS. 1, 2, 3, and 4. In such examples, the pre-power amplifier circuitry sources current from an additional current path, which increases the size of transistors needed to generate the output voltage.

The active termination pre-power amplifier bandwidth 620 represents the bandwidth of the pre-power amplifier circuitry 135, 200, 300, 400, which include the source follower circuitry 155, 220, 440 and the resistors 225, 445 or, more generally, the voltage buffer circuitry 140, 205, 420. In such examples, the source follower circuitry 155, 220, 440 generate a buffered signal that is approximately equal to an output signal to reduce the current through the transistor unit circuitry 160, 165, 170, 245, 250, 465, 470 of FIGS. 1, 2, 3, and 4. Advantageously, decreasing the current through the transistor unit circuitry 160, 165, 170, 245, 465, 470 allows implementations to use relatively smaller and faster switching transistors.

In the example of FIG. 6, the reference pre-power amplifier bandwidth 610 has a cutoff at a first frequency 630 that is approximately equal to two and a half gigahertz (GHz). Also, in the example of FIG. 6, the active termination pre-power amplifier bandwidth 620 has a cutoff at a second frequency 640 that is approximately equal to five and four tenths gigahertz (GHz). Advantageously, the relatively smaller and faster switching transistors increase the bandwidth of the pre-power amplifier circuitry 135, 200, 300, 400. Advantageously, the pre-power amplifier circuitry 135, 200, 300, 400 may be used in applications, such as in radio frequency communications, at higher frequencies.

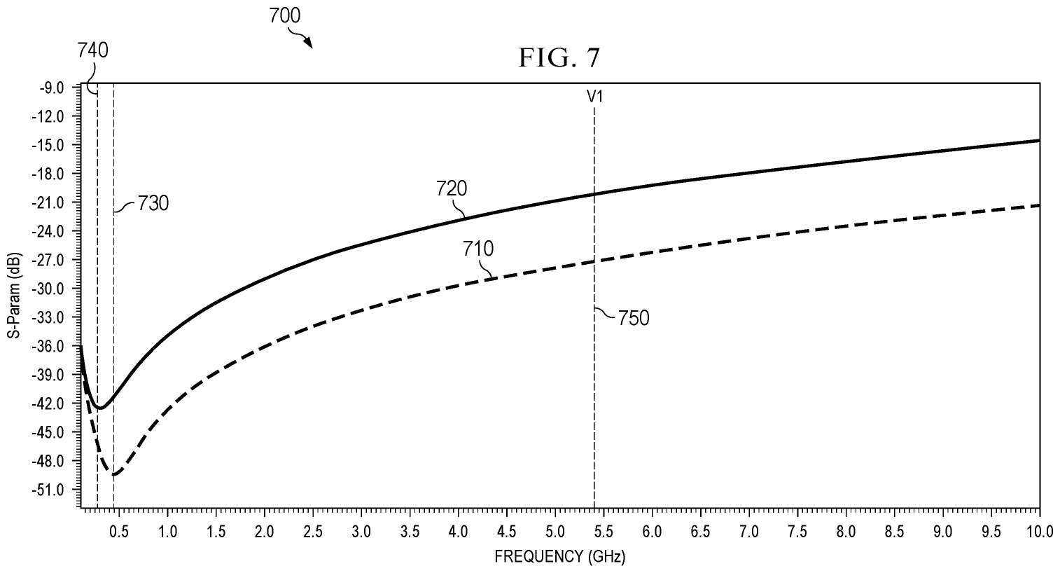

FIG. 7 is a plot 700 of an example noise reflection of the pre-power amplifier circuitry 135, 200, 300, 400 of FIGS. 1, 2, 3, and 4. In the example of FIG. 7, the plot 700 illustrates a reference pre-power amplifier reflection coefficient 710 and an active termination pre-power amplifier reflection coefficient 720. The reference pre-power amplifier reflection coefficient 710 represents the reflected noise of pre-power amplifier circuitry without the source follower circuitry 155, 220, 440 of FIGS. 1, 2, 3, and 4 and the resistors 225, 445 of FIGS. 2, 3, and 4 or, more generally, the voltage buffer circuitry 140, 205, 420 of FIGS. 1, 2, 3, and 4. In the example of FIG. 7, the reference pre-power amplifier reflection coefficient 710 dips at a first frequency 730.

The active termination pre-power amplifier reflection coefficient 720 represents the reflected noise of the pre-power amplifier circuitry 135, 200, 300, 400, which include the source follower circuitry 155, 220, 440 and the resistors 225, 445 or, more generally, the voltage buffer circuitry 140, 205, 420. In such examples, the source follower circuitry 155, 220, 440 generates a buffered signal that is approximately equal to an output signal to reduce the current through the transistor unit circuitry 160, 165, 170, 245, 250, 465, 470 of FIGS. 1, 2, 3, and 4. Advantageously, decreasing the current through the transistor unit circuitry 160, 165, 170, 245, 465, 470 allows implementations to use relatively smaller and faster switching transistors. In the example of FIG. 7, the active termination pre-power amplifier reflection coefficient 720 dips at a second frequency 740. However, after the frequency 740 the active termination pre-power amplifier reflection coefficient 720 increases. Advantageously, at a third frequency 750, which is within the frequency range of RF systems, the active termination pre-power amplifier reflection coefficient 720 has a similar performance to the reference pre-power amplifier reflection coefficient 710, despite having smaller components.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects or things, the phrase “at least one of A and B” refers to implementations including any of (1) at least one A, (2) at least one B, or (3) at least one A and at least one B. Similarly, as used herein in the context of describing structures, components, items, objects or things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real-world imperfections. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+10 milliseconds.

As used herein, the phrase “in communication,” including variations thereof, encompasses direct communication and/or indirect communication through one or more intermediary components, and does not require direct physical (e.g., wired) communication and/or constant communication, but rather also includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to configure and/or structure the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of structure and/or function. These identifiers as used in the detailed description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
voltage buffer circuitry including:
source follower circuitry having a terminal; and
a resistor having a first terminal and a second terminal, the first terminal of the resistor coupled to the terminal of the source follower circuitry; and
driver circuitry including:
a transconductance amplifier having a terminal coupled to the second terminal of the resistor.

2. The apparatus of claim 1, wherein the source follower circuitry includes:
current source circuitry having a terminal; and
a transistor having a terminal coupled to the first terminal of the resistor and the terminal of the current source circuitry.

3. The apparatus of claim 2, wherein the current source circuitry further has a second terminal, and the apparatus further comprising a supply terminal coupled to the second terminal of the current source circuitry.

4. The apparatus of claim 2, wherein the resistor is a first resistor, the terminal of the transistor is a first terminal, the transistor further having a control terminal, the apparatus further comprising:
a second resistor having a terminal; and
a capacitor having a terminal coupled to the control terminal of the transistor and the terminal of the second resistor.

5. The apparatus of claim 2, wherein the resistor is a first resistor, the transistor is a first transistor, the terminal of the first transistor is a first terminal, the first transistor further having a control terminal, the apparatus further comprising:
a second resistor having a terminal;
a second transistor having a first terminal and a second terminal, the first terminal of the second transistor coupled to the control terminal of the first transistor and the terminal of the second resistor; and
a third transistor having a terminal coupled to the second terminal of the second transistor.

6. The apparatus of claim 1, wherein the transconductance amplifier includes:
a first transistor having a first terminal and a second terminal, the first terminal of the first transistor coupled to the second terminal of the resistor; and
a second transistor having a terminal coupled to the second terminal of the first transistor.

7. The apparatus of claim 6, wherein the terminal of the source follower circuitry is a first terminal, the source follower circuitry further having a second terminal, the terminal of the second transistor is a first terminal, the second transistor further having a control terminal, the apparatus further comprising a digital-to-analog converter (DAC) having a first terminal and a second terminal, the first terminal of the DAC coupled to the second terminal of the source follower circuitry, the second terminal of the DAC coupled to the control terminal of the second transistor.

8. The apparatus of claim 1, further comprising power amplifier circuitry having a terminal coupled to the second terminal of the resistor and the terminal of transconductance amplifier.

9. An apparatus comprising:
a digital-to-analog converter (DAC) having a first terminal and a second terminal; and
pre-power amplifier circuitry including:
matching circuitry having a terminal;
voltage buffer circuitry having a first terminal and a second terminal, the first terminal of the voltage buffer circuitry coupled to the first terminal of the DAC; and
driver circuitry having a first terminal and a second terminal, the first terminal of the driver circuitry coupled to the terminal of the DAC, the second terminal of the driver circuitry coupled to the terminal of the matching circuitry and the terminal of the voltage buffer circuitry.

10. The apparatus of claim 9, wherein the voltage buffer circuitry includes:
a resistor having a first terminal and a second terminal, the first terminal of the resistor coupled to the terminal of the matching circuitry and the second terminal of the driver circuitry; and
source follower circuitry having a terminal coupled to the second terminal of the resistor.

11. The apparatus of claim 10, wherein the source follower circuitry includes:
current source circuitry having a terminal; and
a transistor having a terminal coupled to the second terminal of the resistor and the terminal of the current source circuitry.

12. The apparatus of claim 9, wherein the terminal of the DAC is a first terminal, the DAC further having a second terminal, the terminal of the voltage buffer circuitry is a first terminal, the voltage buffer circuitry further having a second terminal, the apparatus further comprising:
a second resistor having a terminal; and
a capacitor having a terminal, coupled to the second terminal of the DAC, the second terminal of the voltage buffer circuitry, and the terminal of the second resistor.

13. The apparatus of claim 9, wherein terminal of the voltage buffer circuitry is a first terminal, the voltage buffer circuitry further having a second terminal, the apparatus further comprising:
a resistor having a terminal;
a first transistor having a first terminal and a second terminal, the first terminal of the first transistor coupled to the second terminal of the voltage buffer circuitry and the terminal of the resistor; and
a second transistor having a first terminal and a control terminal, the first terminal of the second transistor coupled to the second terminal of the first transistor, the control terminal of the second transistor coupled to the terminal of the DAC and the second terminal of the driver circuitry.

14. The apparatus of claim 9, wherein the driver circuitry includes:
first transistor unit circuitry having a first terminal and a second terminal; and
second transistor unit circuitry having a first terminal and a second terminal, the first terminal of the second transistor unit circuitry coupled to the terminal of the matching circuitry, the terminal of the voltage buffer circuitry, and the first terminal of the first transistor unit circuitry, the second terminal of the second transistor unit circuitry coupled to the terminal of the DAC.

15. The apparatus of claim 9, further comprising a power amplifier having a terminal coupled to the terminal of the matching circuitry, the terminal of the voltage buffer circuitry, and the second terminal of the driver circuitry.

16. An integrated circuit comprising:
a first supply terminal;
a second supply terminal;
driver circuitry having a first terminal and a second terminal, the second terminal of the driver circuitry coupled to the first supply terminal;
a resistor having a first terminal and a second terminal, the first terminal of the resistor coupled to the first terminal of the driver circuitry; and
source follower circuitry having a first terminal, a second terminal, and a third terminal, the first terminal of the source follower circuitry coupled to the second terminal of the resistor, the second terminal of the source follower circuitry coupled to the first supply terminal, the third terminal of the source follower circuitry coupled to the second supply terminal.

17. The integrated circuit of claim 16, wherein the driver circuitry further has a third terminal, the source follower circuitry further has a fourth terminal, and the integrated circuit further comprising an digital-to-analog converter (DAC) having a first terminal and a second terminal, the first terminal of the DAC is coupled to the third terminal of the driver circuitry, the second terminal of the DAC is coupled to the fourth terminal of the source follower circuitry.

18. The integrated circuit of claim 16, further comprising matching circuitry having a first terminal and a second terminal, the first terminal of the matching circuitry is coupled to the first terminal of the driver circuitry and the first terminal of the resistor, the second terminal of the matching circuitry is coupled to the second supply terminal.

19. The integrated circuit of claim 16, wherein the driver circuitry includes:
a first transistor having a first terminal and a second terminal, the first terminal of the first transistor is coupled to the first terminal of the resistor; and
a second transistor having a first terminal and a second terminal, the first terminal of the second transistor is coupled to the second terminal of the first transistor, the second terminal of the second transistor is coupled to the first supply terminal.

20. The integrated circuit of claim 16, wherein the first supply terminal is a common terminal that supplies a common potential and the second supply terminal supplies a supply voltage.
